(19) United States
(12) Patent Application Publication
(10) Pub. No.: US 2011/0042208 A1
(43) Pub. Date: Feb. 24, 2011

(54) FILM FORMING SOURCE, VAPOR DEPOSITION APPARATUS, AND APPARATUS FOR MANUFACTURING AN ORGANIC EL ELEMENT

(75) Inventors: Toshio Negishi, Chigasaki-shi (JP); Tatsuhiko KOSHIDA, Chigasaki-shi (JP)

Correspondence Address: KRATZ, QUINTOS & HANSON, LLP, 1420 K Street, N.W., 4th Floor, WASHINGTON, DC, 20005, US

(73) Assignee: ULVAC, INC., Chigasaki-shi (JP)

(21) Appl. No.: 12/862,224

(22) Filed: Aug. 24, 2010

Related U.S. Application Data
(63) Continuation of application No. PCT/JP2009/053578, filed on Feb. 26, 2009.

(30) Foreign Application Priority Data
Feb. 26, 2008 (JP) 2008-044349

(51) Int. Cl. C23C 16/00; C23C 14/34

(52) U.S. Cl. 204/298.02; 118/715; 118/728

(57) ABSTRACT

A film forming source capable of forming a thin film having a good film quality is provided. Since each switch valve becomes a closed state when a blocking member closely contacts a melted metal, a gas blocking performance in the closed state is high, and no dust is generated. When vapors of different vapor deposition materials are generated in a plurality of vapor generating units, the vapor generated in a selected vapor generating unit is not mixed with the vapor from another vapor deposition apparatus. Therefore, a vapor deposition material not to be film-formed is not mixed in, and contamination due to dust generation does not occur. Consequently, a thin film having good film quality can be obtained.

This application is a continuation of International Application No. PCT/JP2009/053578 filed Feb. 26, 2009, which claims priority to Japanese Patent Document No. 2008-044349, filed on Feb. 26, 2008. The entire disclosures of the prior applications are herein incorporated by reference in their entireties.

### BACKGROUND OF INVENTION

The present invention generally relates to a vapor deposition apparatus, and more particularly to a vapor deposition apparatus to be used for manufacturing organic EL elements.

### BACKGROUND ART

The organic EL element is one of light emitting elements which have recently become most attracted, and has excellent characteristics such as high brightness and a high response speed.

In the organic EL element, a lower electrode film, an organic thin film, and an upper electrode film are laminated on a glass substrate in the order as described.

The organic thin film includes a hole injection layer, a hole transport layer, a light emitting layer, an electron transport layer, an electron injection layer, etc. When current is passed through the lower electrode film and the upper electrode film and a voltage is applied to the organic thin film, the light emitting layer emits light.

When the light emitting layer is constituted by laminating color layers of three or more colors (for example, red, green, blue, yellow) at the same position, it emits white light, so that the organic EL element can be used as an illuminating device. Further, when light emitting layers are constructed by forming color layers of three or more colors (for example, red, green, blue) at different positions, an organic EL element can be used as a full-color display device by applying voltage to the color layers of desired colors at desired positions.

Each of the layers constituting the organic thin film is constituted by an organic material, and the film of such an organic material is formed by using a vapor deposition apparatus.

In FIG. 9, a reference numeral 203 denotes a conventional vapor deposition apparatus, and a vapor deposition vessel 212 is arranged inside a vacuum chamber 211. The vapor deposition vessel 212 has a vessel body 221, and an upper portion of the vessel body 221 is covered with a lid portion 222 in which one or plural discharge openings 224 are formed.

A powder of an organic vapor deposition material 200 is disposed inside the vapor deposition vessel 212.

A heater 223 is arranged at a lateral side and a bottom face of the vapor deposition vessel 212. When the interior of the vacuum chamber 211 is evacuated to vacuum and the heater 223 generates heat, the temperature of the vapor deposition vessel 212 is raised, and the organic vapor deposition material 200 inside the vapor deposition vessel 212 is heated.

When the organic vapor deposition material 200 is heated to the evaporation temperature or higher, a vapor of the organic material fills inside the vapor deposition vessel 212, and is discharged into the vacuum chamber 211 through the discharge openings 224.

A holder 210 is arranged above the discharge openings 224; and when a substrate 205 is held at the holder 210, the vapor of the organic material discharged through the discharge openings 224 reaches a surface of the substrate 205, so that an organic thin film, such as a hole injection layer, a hole transport layer, or a light emitting layer, is formed. When the substrates 205 are passed one by one above the discharge openings 224 while the vapor of the organic material is discharged, organic thin films can be formed successively on a plurality of substrates 205.

However, in order to form the films on a plurality of substrates 205, it is necessary to place a large amount of the organic material inside the vapor deposition vessel 212. In an actual production site, while the organic material is heated at 250° C. to 450° C., the film formation is performed continuously for 120 hours or more. Consequently, the organic vapor deposition material 200 inside the vacuum deposition vessel 212 is exposed to the high temperature for a long time, so that it reacts and is modified with moisture in the vapor deposition vessel 212, or its decomposition continues to occur while it is heated. As a result, the organic vapor deposition material 200 is deteriorated as compared to an initial state thereof, so that the film quality of the organic thin film worsens.

In addition, when plural color layers need to be formed as in the case of the above-mentioned light emitting layers, a plurality of vapor deposition vessels 212 in which organic materials having different colors are placed are prepared, and films are formed by moving a substrate above the respective vapor deposition vessels 212. However, when the amount of the substrate that is moved increases, dust is generated, thereby causing deterioration in the quality of the film on the substrate.

Further, when a large substrate 205 is held above the discharge openings 224, the substrate 205 or the mask 214 is sagged, so there are problems in that a film (a lower electrode film or other organic thin film) preliminarily formed on the surface of the substrate 205 is damaged or the film thickness distribution of an organic thin film newly formed on the substrate 205 is poor. See patent documents JP-A 2001-523768, JP-A 2003-525349, JP-A 2004-204289, JP-A 2005-29885, and JP-A 2006-111920.

### SUMMARY OF THE INVENTION

The present invention is aimed at solving the above-discussed problems, and its object is to form an organic thin film having a good film quality.

In order to solve the above-discussed problems, the present invention is directed to a film forming source which comprises a vapor generating unit for generating a vapor of a vapor deposition material therein, a discharging unit for discharging the vapor of the vapor deposition material, and a switch valve for switching connection and blocking between the vapor generating unit and the discharging unit, wherein the switch valve includes a box body, a vessel which is arranged inside the box body and in which a melted metal is to be placed, the melted metal placed in the vessel, a blocking member having a lower end being capable of contacting the melted metal, and a moving unit which closes the switch valve by relatively moving the blocking member and contacting the lower end of the blocking member with a surface of the melted metal and opens the switch valve by spacing the lower end of the blocking member apart from the surface of the melted metal.

The present invention is directed to the film forming source, which comprises a plurality of the vapor generating units, wherein connection and blocking between the vapor generating units and the discharging unit can be individually switched by the switch valve.

The present invention is directed to the film forming source, wherein the blocking member is in the form of a tube, the lower end of the blocking member is constructed by a lower end of the tube, either one of the discharging unit and the vapor generating units is connected to an inner space of the tube, and the other is connected to an outer space of the tube.

The present invention is directed to the film forming source, which comprises a pipe having a tip inserted into the box body and surrounded by the vessel, and a lid portion, wherein the tubular blocking member which comprises a ring-shaped projection formed projectingly from a bottom face of the lid portion is formed on the bottom face of the lid portion, wherein when the blocking member contacts the low-melting point metal melted inside the vessel over an outer circumference of the pipe, an on-off opening is blocked by the blocking member and the lid portion and the switch valve is closed, and wherein when the blocking member moves away from the low-melting point metal, the switch valve is opened.

The present invention is directed to the film forming source, wherein the discharging unit includes a plurality of elongate discharge pipes arranged parallel to each other, a discharge opening is provided in each of the discharge pipes, respectively, and when the vapor generating units are connected to the discharging unit, the vapor of the vapor deposition material is fed into each of the discharge pipes, respectively, and the vapor of the vapor deposition material is discharged through each of the discharge openings.

The present invention is directed to a vapor deposition apparatus, which comprises a film forming chamber and the above film forming source, wherein the discharging unit discharges the vapor of the vapor deposition material into the film forming chamber.

The present invention is directed to the vapor deposition apparatus, which comprises a mounting board which is arranged inside the film forming chamber and on a surface of which a substrate is to be placed, wherein the discharging unit discharges the vapor of the vapor deposition material toward the mounting board from a position above the mounting board.

The present invention is directed to the vapor deposition apparatus, which comprises an oscillating unit connected to either one or both of the mounting board and the discharging unit, wherein the oscillating unit moves the discharging unit relative to the substrate within a plane parallel to the substrate placed on the mounting board.

The present invention relates to a manufacturing apparatus for an organic EL element, which comprises a transfer chamber, a sputtering chamber, and a vapor deposition apparatus, wherein the sputtering chamber and the vapor deposition apparatus are connected to the transfer chamber.

Since the present invention is constructed as discussed above, when the gas containing the vapor of the organic material flows from the vapor generating unit through the switch valve in the opened state, the vapor moves into the discharging unit through the switch valve.

On the other hand, when the switch valve sets in the closed state by contacting the blocking member with the melted metal and the gas containing the vapor of the organic material flows from the vapor generating unit to the switch valve, the vapor is blocked by the melted metal and the blocking member and stays in the vapor generating unit and the switch valve, thereby not moving to the discharging unit.

Since the blocking member closely contacts the melted metal without a gap, the blocking performance against the gas is higher than in a case where the blocking member contacts a solid. In addition, even when the switch valve is repeatedly opened and closed, the lower end of the blocking member is not abraded, so that no dust is generated.

### EFFECTS OF THE INVENTION

Since the blocking performance against the gas is high, the thin film having a high purity is formed without vapor of the vapor deposition material being mixed. Since no dust is generated, no pollutant is mixed into the thin film. Since the switch valve is not abraded, the film forming source has a long life-span. Since the vapors generated in the plural vapor generating units can be supplied into the discharging unit in order, plural kinds of films can be formed on the substrate in a state such that the substrate is kept arranged above the same discharging unit. Since the amount of substrate that is moved is smaller, no dust is generated.

### BRIEF DESCRIPTION OF THE DRAWINGS

FIG. 1 is a plan view for illustrating one embodiment of a manufacturing apparatus.

FIG. 2 is a schematic plan view for illustrating one embodiment of a vapor deposition apparatus of the present invention.

FIG. 3 is a sectional view along line A-A shown in FIG. 2.

FIG. 4 is a sectional view for illustrating one embodiment of a vapor generating unit.

FIG. 5(a) is a sectional view for illustrating a closed state, and FIG. 5(b) is a sectional view for illustrating an opened state.

FIG. 6 is a sectional view for illustrating a second embodiment of a switch valve.

FIG. 7 is a sectional view for illustrating a third embodiment of a switch valve.

FIG. 8 is a sectional view for illustrating a fourth embodiment of a switch valve.

FIG. 9 is a sectional view for illustrating a conventional vapor deposition apparatus.

FIG. 10(a) and (b) are views for illustrating other embodiments of the present invention.

FIG. 11 is a view for illustrating an embodiment of the present invention connected to a cooling unit (blocked from a cooling chamber).

FIG. 12 is a view for illustrating the embodiment of the present invention connected to the cooling unit (connected to the cooling chamber).

FIG. 13 is an embodiment (closely attached state) in which a second on-off opening connected to the cooling unit is attached and detached relative to a bottom face of a first vessel.

FIG. 14 is an embodiment (detached state) in which the second on-off opening connected to the cooling unit is attached and detached relative to a bottom face of the first vessel.

### DETAILED DESCRIPTION OF THE INVENTION

The switch valve of the present invention comprises a housing being a box body, and an on-off opening and a connection opening through which an interior and an exterior of the housing are communicated, respectively, wherein switching is performed between a connected state in which a gas passes through the interior of the housing and a blocked state in which the on-off opening and the connection opening are blocked. The box body is gas-tightly constructed, and can be evacuated to vacuum.

The switch valve of the present invention is arranged inside the housing, and comprises a vessel in which a solid and a liquid can be placed, and a blocking member arranged inside the housing.

The vessel and the blocking member are constructed so as to be able to move relative to each other so that the blocking member may be inserted into and pulled away from the vessel. The on-off opening is surrounded by either one of the blocking member and the vessel.

A low-melting point metal can be placed in the vessel. In the case where a melted metal is formed by melting the low-melting point metal which is placed in the vessel, when the blocking member is inserted into the vessel, the blocking member contacts the melted metal and is immersed. Consequently, the contacting portion and the immersed portion surround the on-off opening, and the on-off opening is closed. When the blocking member is pulled away from the interior of the vessel, the blocking member is taken away from the melted metal, and the on-off opening is opened.

A pipe is gas-tightly inserted into the housing; a tip of the pipe inside the housing is directed downwardly; and the vessel is arranged under the on-off opening. The housing is provided with a connection opening, and assuming that the opening at a tip of the pipe inside the housing is taken as an on-off opening, the on-off opening is connected to the connection opening when the tip of the pipe is spaced apart from the melted metal inside the vessel. Assuming that a portion surrounding the on-off opening at the tip of the pipe within the housing is a ring-shaped blocking member, when the vessel and the pipe are relatively moved and the entire circumference of the blocking member contacts the melted metal and is immersed within the vessel, the pipe is closed, and the on-off opening is blocked from the connection opening.

Apart from the above, the opening at the tip of this pipe becomes the on-off opening when the pipe is gas-tightly inserted into the housing, the tip of the pipe inside the housing is directed upwardly and the circumference of the tip of the pipe is surrounded by the vessel. When a tubular blocking member being a ring-shaped projection is gas-tightly formed on a bottom face of a lid portion being a lid, which does not permit a gas to pass, the melted metal inside the vessel which surrounds the on-off opening and the blocking member contact along the entire circumference of the on-off opening outside the on-off opening and the blocking member is immersed therein, so that the on-off opening is covered and closed with the lid portion and the blocking member. When the housing is provided with a connection opening, the on-off opening is blocked from the connection opening in a state such that the on-off opening is covered with the lid, whereas when the blocking member is spaced apart from the melted metal and the lid is opened, the on-off opening is connected to the connection opening.

According to the present invention, a moving unit can be provided, which relatively moves the vessel and the blocking member as discussed above. Opening and closing may be performed by moving either one or both of the blocking member and the vessel.

In addition, the switch valve of the present invention includes a box body, and a connection opening which communicates with the interior and the exterior of the box body, respectively, and first and second on-off openings, wherein switching can be performed between a first state in which a gas can pass through the interior of the box body between the first on-off opening and the connection opening while the second on-off opening is closed and a second state in which the gas can pass through the interior of the box body between the second on-off opening and the connection opening while the first on-off opening is closed. The switch valve comprises first and second vessels which are arranged in the box body and in which a solid and a liquid can be placed, respectively, and tubular first and second blocking portions which are arranged inside the box body and can be inserted into and pulled away from the first and second vessels, respectively, wherein a melted low-melting point metal is placed in the first and second vessels; and when the first vessel is positioned downwardly inside the box body, the first blocking portion is pulled away from the first vessel and the second blocking portion is inserted into the second vessel and contacts the low-melting point metal in order to attain the first state; whereas when the first vessel is positioned upwardly, the first blocking portion is inserted into the first vessel and contacts the low-melting point metal and the second blocking portion is pulled away from the second vessel in order to attain the second state.

Next, embodiments of the present invention will be explained.

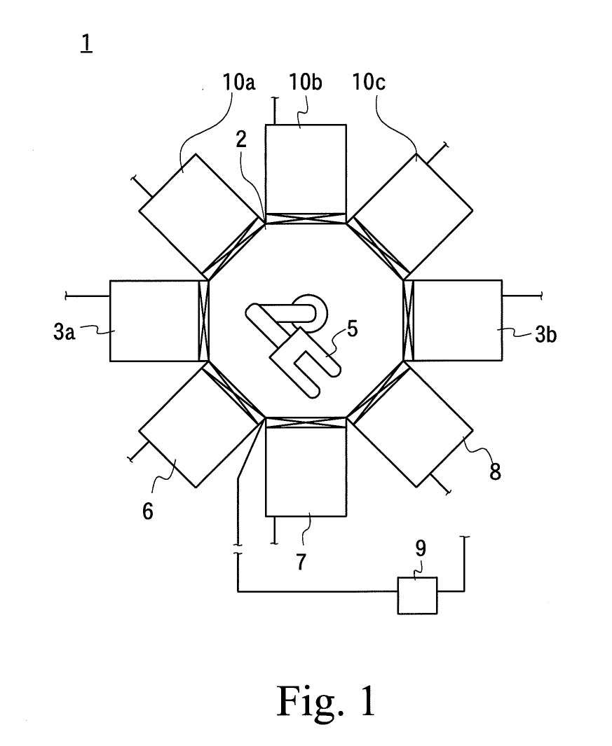

In FIG. 1, a reference numeral 1 denotes one embodiment of a manufacturing apparatus of the present invention to be used for manufacturing organic EL elements.

This manufacturing apparatus 1 includes a transfer chamber 2, one or plural vapor deposition apparatuses 10a to 10c, a sputtering chamber 7, carrying-in-and-out chambers 3a, 3b, and processing chambers 6, 8. Each of the vapor deposition apparatuses 10a to 10c, the sputtering chamber 7, the carrying out/in chambers 3a, 3b and the processing chambers 6, 8 are connected to the transfer chamber 2, respectively.

A vacuum evacuation system 9 is connected to the transfer chamber 2, each of the vapor deposition apparatuses 10a to 10c, the sputtering chamber 7, the carrying-in-and-out chambers 3a, 3b and each of the processing chambers 6, 8.

Vacuum atmospheres are formed, by the vacuum evacuation system 9, inside the transfer chamber 2, inside the vapor deposition apparatuses 10a to 10c, inside the processing chambers 6,8, inside the sputtering chamber 7, inside the carrying-in chamber 3a and inside the carrying-out chamber 3b.

A transfer robot 5 is arranged inside a transfer chamber 2, a substrate is transferred in the vacuum atmosphere by the transfer robot 5 and is subjected to a pretreatment (such as, heating or cleaning) inside the processing chambers 6, 8; and a transparent conductive film (lower electrode) is formed on a surface of the substrate inside the sputtering chamber 7. Organic thin films (such as, an electron injection film, an electron transport layer, a light emitting layer, a hole transport layer or a hole injection layer) are formed inside the vapor deposition apparatuses 10a to 10c; and an upper electrode is formed inside the sputtering chamber 7, thereby obtaining an organic EL element. The obtained organic EL element is carried out from the carrying-out chamber 3b.

In this connection, it may be that, before a substrate is carried into the manufacturing apparatus 1, a thin film transistor and a lower electrode are preliminarily formed on a surface of the substrate by another manufacturing apparatus; and after the lower electrode is patterned in a predetermined shape, if necessary, the substrate is carried into the above-discussed manufacturing apparatus 1; and an organic thin film and an upper electrode are formed.

Next, an apparatus and a method for forming a light emitting layer will be explained below.

In FIG. 1, at least one of the vapor deposition apparatuses 10a to 10c is constituted by the vapor deposition apparatus 10b of the present invention, and the above light emitting layer is formed by using the vapor deposition apparatus 10b of the present invention.

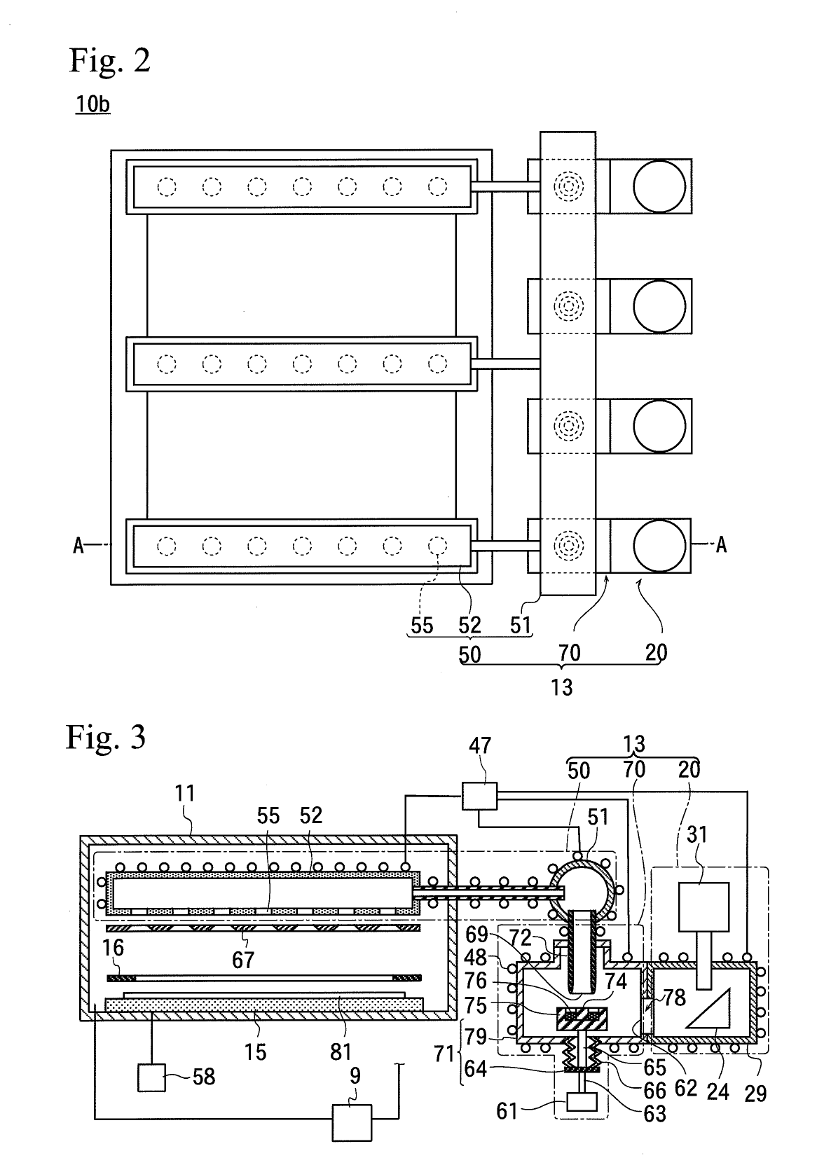

FIG. 2 is a schematic plan view for illustrating the vapor deposition apparatus 10b of the present invention; and the vapor deposition apparatus 10b includes a film forming chamber and a film forming source 13. In FIG. 2, the film forming chamber is omitted.

The film forming source 13 includes a discharging unit 50, a plurality of vapor generating units 20, and switch valves 70 having the same number as that of the vapor generating units 20 or more.

The respective vapor generating units 20 have the same construction except that different vapor deposition materials are received, so that an explanation will be made using the same reference numerals as before.

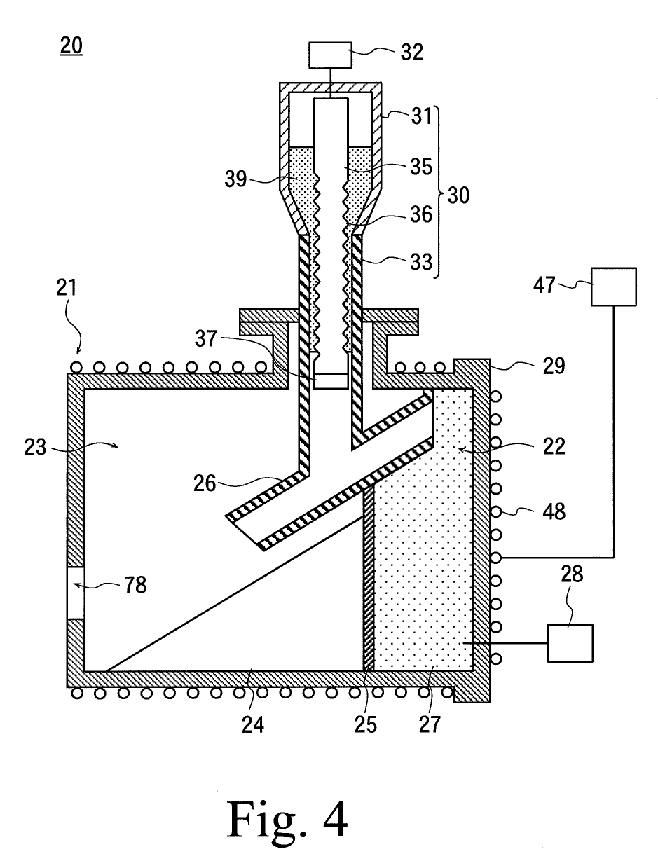

FIG. 4 is a sectional view of the vapor generating unit 20, the vapor generating unit 20 having a heating device 21 and a feeding device 30.

The heating device 21 has a heating chamber 29. The interior space of the heating chamber 29 is divided into two sections by a partition member 25, a filter 27 made of ceramic particles (SiC particles or the like) or meshes or the like is placed in one introduction space 22, and a mounting member 24 is placed in the other heating space 23.

The heating chamber 29 is fitted with heating means 48, so that when a current is applied to the heating means 48 from a power source 47, the heating chamber 29 is heated, and the mounting member 24 and the filter 27 are also heated due to heat conduction and radiation heat. Besides the heating chamber 29, either one or both of the mounting member 24 and the filter 27 are fitted with independent heating means, and are heated directly with the heating means.

An introduction pipe 26 is arranged inside the heating chamber 29; one end of the introduction pipe 26 is connected to the introduction space 22; and the other end is connected to the heating space 23. A gas introduction system 28 is connected to the introduction space 22. When the filter 27 is heated and a purge gas is introduced from the gas introduction system 28, the purge gas is heated when it passes the filter 27; and the heated purge gas is fed into the introduction pipe 26 and the heating space 23.

The feeding device 30 includes a tank 31, a connection pipe 33 and a rotary shaft 35.

The tank 31 is arranged above the heating chamber 29, and the upper end of the connection pipe 33 is gas-tightly connected to the inner space of the tank 31. The lower end of the connection pipe 33 is gas-tightly inserted into the heating chamber 29, and is connected between one end and another end of the introduction pipe 26.

A convex portion 36 is spirally formed around the rotary shaft 35, and the rotary shaft 35 is inserted into the connection pipe 33 such that at least a part of the convex portion 36 is located inside the connection pipe 33. FIG. 4 shows a state in which a vapor deposition material 39 is received in the tank 31.

The vapor deposition material 39 stays in the tank 31 in such a state that the rotary shaft 35 remains still. When the rotary shaft 35 is rotated around a central axis of the connection pipe 33 by rotary means 32, the vapor deposition material 39 inside the tank 31 enters grooves between convex portions 36, so that the vapor deposition material 39 moves downwardly inside the connection pipe 33 through the grooves, and drops between one end and another end of the introduction pipe 26.

If the relationship between a rotated amount of the rotary shaft 35 and a dropping amount of the vapor deposition material 39 is determined, a rotary amount of the rotary shaft 35 required for dropping a necessary amount of the vapor deposition material 39 can be predicted from the relationship thereof.

At least a portion of the introduction pipe 26 on a side of the heating space 23, as viewed from a fallen position of the vapor deposition material 39, is inclined downwardly such that the fallen position is up and the end portion (lower end) on the side of the heating space 23 is down. Thus, the vapor deposition material 39 gravitationally moves toward the lower end from the fallen position through the interior of the introduction pipe 26, and falls into the heating space 23 through the lower end.

A surface of the mounting member 24 is located immediately under the lower end of the introduction pipe 26, the fallen vapor deposition material 39 being placed on the surface of the mounting member 24. The surface of the mounting member 24 is inclined from the horizontal plane. The fallen position where the vapor deposition material 39 is placed on the surface of the mounting member 24 is above the lower end of the surface, and the vapor deposition material 39 gravitationally moves on the surface of the mounting member 24 toward the lower end. When the mounting member 24 is heated to the evaporation temperature of the vapor deposition material 39 or higher, the vapor deposition material 39 is completely evaporated before it reaches the lower end of the surface of the mounting member 24, and vapor is generated in the heating space 23.

One or more switch valves 70 are provided between each of the vapor deposition units 20 and the discharging unit 50.

The heating space 23 is connected to the switch valve 70. Next, the switch valve 70 will be explained in detail. Each of the switch valves 70 has the same construction, and explanation will be made using the same reference numerals as before.

FIG. 3 is a sectional view along line A-A shown in FIG. 2. Each switch valve 70 includes a box body 71 being a housing, a vessel 75, a blocking member 72, and a moving unit 61.

A part of a bottom wall of the box body 71 is separated. Reference numeral 64 in FIG. 3 denotes a lower box body portion, which is separated, and reference numeral 79 denotes a remaining upper box body portion.

An extensible member (for example, a bellows 66) is arranged between the upper box body portion 79 and the lower box body portion 64; and a space between the upper box body portion 79 and the lower box body portion 64 is blocked from the outside by the bellows 66. Therefore, the inner space of the box body 71 is blocked from the outer space.

An upper shaft 65 is inserted through the bellows 66, and a lower end of the upper shaft 65 is fixed to the lower box body portion 64. A vessel 75 is attached to the upper end of the upper shaft 65 in such a state that an opening of the vessel is directed upwardly.

The lower end of the lower shaft 63 is connected to the moving unit 61. When the lower shaft 63 is moved up or down by the moving unit 61, the bellows 66 contracts or extends; and the lower box body portion 64, the upper shaft 65 and the vessel 75 move up or down together in such a state that the inner space of the box body 71 is kept blocked from the outer space.

A blocking member 72 is constituted by a tube (pipe); and the tube is gas-tightly inserted into the upper box body portion 79 such that one end (lower end) of the tube is faced toward the opening of the vessel 75.

The lower box body portion 64 moves, whereas the upper box body portion 79 is fixed. The blocking member 72 is fixed to the upper box body portion 79, and the vessel 75 and the blocking member 72 moves relative to each other, when the vessel 75 moves up or down.

A projection 74 having a diameter smaller than that of the opening of the vessel 75 is erected in an almost central position of a bottom face of the vessel 75, and a ring-shaped receiving portion is formed between a lateral wall of the vessel 75 and a lateral face of the projection 74.

The opening of the lower end of the pipe inserted into the upper box body portion 79 is an on-off opening 69; and a pipe tip portion around the on-off opening 69 is the blocking member 72. As described later, the on-off opening 69 is opened or closed by the blocking member 72.

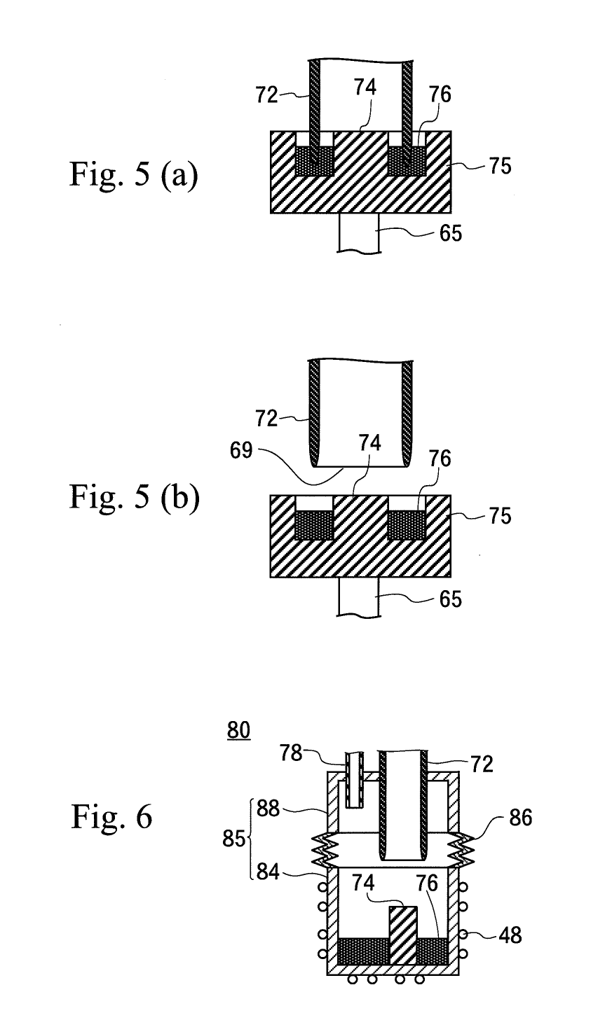

FIGS. 5(a) and (b) and FIG. 3 show a low-melting point metal 76 being placed in the vessel 75. Since the vessel 75 is positioned inside the box body 71, the low-melting point metal 76 is indirectly placed inside the box body 71 through the vessel 75.

The box body 71 is fitted with heating means 48, such as a heater. The vessel 75 and the projection 74 are heated with radiation heat when the box body 71 is heated, or heated with the heating means 48 attached to the vessel 75, so that the low-melting point metal 76 becomes ring-shape when being heated.

The outer circumference of the lower end of the blocking member 72 is smaller than the opening of the vessel 75; and the inner circumference of the lower end of the blocking member 72 is larger than the tip of the projection 74. The outer circumference and the inner circumference of the lower end of the blocking member 72 are positioned between an edge of the opening of the vessel 75 and the outer circumference of the tip of the projection 74; and the entire circumference of the lower end of the blocking member 72 faces towards the surface of the melted low-melting point metal 76.

When the vessel 75 is moved up and the melted low-melting point metal 76 is moved close to the lower end of the blocking member 72, the entire circumference of the lower end of the blocking member 72 contacts the surface of the low-melting point metal 76, so that a closed state is formed, in which the inner space of the box body 71 is divided into the inner space of the blocking member 72 and the outer space of the blocking member 72 (FIG. 5(a)).

On the other hand, when the vessel 75 is moved down and the blocking member 72 is moved away and spaced apart from the melted low-melting point metal 76, an opened state is formed, in which the inner space of the blocking member 72 is connected to the outer space and the inner space of the box body 71 is integrated (FIG. 5(b)).

A through hole is formed in a lateral face of the upper box body portion 79, and a connection pipe 78 is constituted by the through hole or a pipe gas-tightly inserted through the through hole. The upper end of the blocking member 72 is extended gas-tightly from the box body 71. The inner space of the box body 71 is connectable with an outside apparatus through the connection pipe 78 and the blocking member 72 only.

Either the vapor generating unit 20 or the discharging unit 50 is gas-tightly connected to the connection pipe 78, while the other is gas-tightly connected to the blocking member 72.

Since the inner space and the outer space of the blocking member 72 within the box body 71 are blocked from the outer space (the atmosphere, for example) by the box body 71 and the bellows 66, when the switch valve 70 is switched into the opened state, the gas containing the vapor of the vapor deposition material 39 is moved from the vapor generating unit 20 to the discharging unit 50 through the inner space of the box body 71 without leaking into the exterior.

In contrast, when the switch valve 70 is switched into the closed state, the above-described gas stays in the vapor generating unit 20 and a part of the switch valve 70 (the inner space or the outer space of the blocking member 72) without leaking into the outside.

Since the switch valves 70 can be individually switched between the opened state and the closed state, the vapor generating units 20 can be individually connected to or blocked from the discharging unit 50, and the gas can be moved from a desired vapor generating unit 20 to the discharging unit 50.

Each switch valve 70 is connected to one discharging unit 50. Therefore, the vapor generated in each vapor generating unit 20 is fed into one discharging unit 50.

The discharging unit 50 has a plurality of discharge pipes 52.

Each discharge pipe 52 is elongate, and a plurality of discharge openings 55 is provided at a constant interval in a row for each discharge pipe 52 along its longitudinal direction. The respective discharge pipes 52 are arranged in parallel inside the film forming chamber 11 such that each discharge opening 55 is directed downwardly. Therefore, the discharge openings 55 are arrayed in a matrix.

Each of the discharge pipes 52 is connected to the corresponding switch valve 70 via a common pipe 51; and when the switch valve 70 is opened, the vapor is fed into the respective discharge pipes 52 from the vapor generating unit 20 connected to the switch valve 70.

A discharge path (each discharge pipe 52, the common pipe 51) through which the vapor of the discharging unit 50 passes is provided with heating means 48. If the discharge path is heated by the heating means 48 to a temperature at which the vapor does not form a deposition, the vapor is discharged through the respective discharge opening 55 without forming the deposition while the vapor is being discharged.

As described above, since each of the discharge openings 55 is directed downwardly, the vapor is ejected downwardly through the discharge openings 55. A mounting board 15 is arranged under an area where the discharge openings 55 are arrayed in the film forming chamber 11. A substrate 81 carried into the film forming chamber 11 is placed on a surface of the mounting board 15, and the vapor discharged through the discharge openings 55 are blown onto a surface of the substrate 81 on the mounting board 15. A face of the mounting board 15 on which the substrate 81 is placed is so wide that not less than a half of the rear face of the substrate 81 may contact it. Therefore, even if the substrate 81 is large in size, deformation, such as sagging, does not occur.

Next, a step for forming a light emitting layer by using this vapor deposition apparatus 10b will hereinafter be explained.

Vapor deposition materials 39 of two or more colors are prepared by mixing a luminescent organic material and coloring agents. When a light emitting layer for a white light is to be formed, vapor deposition materials 39 of at least three colors (red, green, blue, for example) are prepared.

Explanation is provided on the assumption that any one of three colors (that is, red, green or blue) is taken as a first color, either one of the remaining two colors is taken as a second color, and the other as a third color. In order to approach the white light to more white, vapor deposition materials 39 of one or more auxiliary colors (for example, yellow) are also prepared in addition to the first to third colors.

The film thickness of the coloring layer of each of the colors to be film-formed is preliminarily determined, and a necessary amount of the vapor deposition material 39 required to form a film in a predetermined film thickness is preliminarily determined for each of the colors.

Each heating chamber 29, each tank 31, each box body 71 and the film forming chamber 11 are connected to the vacuum evacuation system 9, respectively, while a vacuum atmosphere having a predetermined pressure (for example, 10⁻⁵ Pa) is formed by evacuating each heating chamber 29, each tank 31, each box body 71 and the film forming chamber 11. Since the discharging unit 50 is connected to the interior of the film forming chamber 11 through the discharge openings 55, a vacuum atmosphere is also formed inside the discharging unit 50. While the vacuum atmosphere of each tank 31 is maintained, the organic materials of the respective colors are placed in the tanks 31 of the different vapor generating units 20, respectively.

The mounting member 24 is heated to an evaporating temperature at which the vapor deposition material 39 evaporates (300° C. or more and 400° C. or less) by passing current through each heating means 48, and those members (such as the heating chamber 29, the box body 71, the discharging unit 50, the vessel 75, and the projection 74), which contact the vapor, is heated to a heating temperature (240° C. or more and 400° C. or less) over a temperature at which the vapor of the vapor deposition material 39 forms a deposition. The low-melting point metal 76 having the melting point not higher than the heating temperature is preliminarily placed in the respective vessels 75, and the low-melting point metal 76 is melted.

The purge gas is fed into the heating space 23 of each of the vapor generating units 20, respectively. Since the filter 27 is heated to the heating temperature, the purge gas heated to the heating temperature is fed to the heating space 23. In each vapor generating unit 20, the mounting member 24 is maintained at the evaporating temperature; and the members which contact the vapor are maintained at the heating temperature.

The vacuum evacuation of the heating chamber 29 of the vapor generating unit 20 in which the vapor deposition material 39 of the first color is received and the vacuum evacuation of the switch valve 70 connected to the heating chamber 29 are stopped, whereby the vapor generating unit 20 becomes a film forming state. The pre-determined required amount of the vapor deposition material 39 of the first color is dropped into the heating space 23 in order to generate the vapor.

While the vacuum evacuation of the film forming chamber 11 is continued, the switch valve 70 between the vapor generating unit 20 in which the vapor is generated and the discharging unit 50 is opened, and the other switch valves 70 between the other vapor generating units 20 and the discharging unit 50 are closed.

The vapor is discharged through the discharge openings 55 together with the purge gas through the switch valve 70 and the discharging unit 50 without moving into the other vapor generating units 20.

Before the vapor is discharged through the discharge openings 55, the substrate 81 is preliminarily carried into the film forming chamber 11, and placed on the surface of the mounting board 15.

The substrate 81 on the mounting board 15 is faced toward the area where the discharge openings 55 are arrayed during a period from a time when the vapor begins to be discharged through the discharge openings 55 to a time when the discharging of the vapor is finished and the film formation is terminated.

When a predetermined time passed after the falling of the vapor deposition material 39 or when the inner pressure of the heating space 23 becomes a predetermined pressure or less, it is judged that the film formation is terminated. When the film formation is terminated, the color layer of the first color is formed in a predetermined film thickness on the surface of the substrate 81. After the film formation, the vacuum evacuation of the heating chamber 29 and the switch valve 70 is started again and the remaining vapor is discharged.

While the substrate 81 is placed on the mounting board 15, the vapor generating unit 20 placed in the film forming state is changed from one, in which the vapor deposition material 39 of the first color is disposed, to another, in which the vapor deposition material 39 of the second color is disposed.

The switch valves 70 are switched such that the switch valve 70 between the vapor generating unit 20 in the film forming state and the discharging unit 50 is opened, whereas the switch valves 70 between other vapor generating units 20 and the discharging unit 50 are closed. The vapor of a necessary amount of the vapor deposition material 39 of the second color is generated, and a color layer of the second color is formed in a predetermined film thickness on the surface of the substrate 81 as is the case with the first color.

After the termination of the film formation, if the discharging of the remaining vapor, the change of the vapor generating unit 20 in the film-forming state, the switching of the switch valves 70, and the film forming of a color layer of the third color are performed, while the substrate 81 is placed on the mounting board 15, the light emitting layer made of the color layers of the first to third colors is formed on the surface of the substrate 81.

When a light emitting layer is obtained by forming color layers of one or more auxiliary colors (for example, yellow), besides the first to third colors, the color layer(s) of the auxiliary color (s) is (are) formed in the same method as in the formation of the color layers of the first to third colors before the color layers of the first to third colors are formed, during the period when the color layers of the first to third colors are formed or after the color layers of the first to third colors are formed.

When the light emitting layer is formed without using a mask 16 or when the light emitting layer is formed in a state such that the mask 16 is kept still relative to the substrate 81 between the area in which the discharge openings 55 are arrayed and the substrate 81, the color layer of each color is laminated on the surface of the substrate 81 at the same places.

If the mask 16 and the substrate 81 are moved relative to each other every time the color of the color layer to be film-formed is changed, the color layers of the respective colors are formed at different places on the surface of the substrate 81, respectively.

Both when the color layers are laminated at the same place and when the color layers are formed at the different places on the surface of the substrate 81, white color light is emitted if light is emitted by passing current between the upper electrode and the lower electrode and applying a voltage to each color layer.

When the color layers are formed at different places, either the lower electrode or the upper electrode is patterned and voltage can be individually applied to each of the color layers; and letters or images can be displayed in full color by emitting lights from the color layers of desired colors at desired positions.

If, while the color layer is formed, the purge gas is continuously introduced in a state such that the filter 27 is kept heated to the heating temperature, the vapor flows away due to the purge gas, so that the vapor of the necessary amount of the vapor deposition material 39 can be completely discharged through the discharge openings 55, whereby the film thickness of the color layer can be accurately controlled. Further, if the introduction of the purge gas continues when discharging the remaining vapor, the discharging is performed in a short time.

The above explanation is directed to the case where the low-melting point metal 76 is disposed in the vessel 75, but the present invention is not limited thereto. In FIG. 6, reference numeral 80 denotes a switch valve of a second embodiment of the present invention. In the switch valve 80, the low-melting point metal 76 is placed directly in a lower box body portion 84 of a box body 85.

Similar to FIG. 3, a blocking member 72 and a connection pipe 78 are gas-tightly inserted into an upper box body portion 88, and the upper box body portion 88 is fixed. The lower box body portion 84 and the upper box body portion 88 are gas-tightly connected to a bellows 86 so that they may move relative to each other. A moving unit (not shown) is attached to the lower box body portion 84; the lower box body portion 84 is moved up and down by the moving unit; and the low-melting point metal 76 placed in the lower box body portion 84 moves relative to the lower end of the blocking member 72.

The above explanation is directed to the case where the upper box body portion 88 is fixed and the lower box body portion 84 moves, but the present invention is not limited thereto. It may be that the lower box body portion 84 is fixed and the upper box body portion 88 is moved up and down by connecting the moving unit to the upper box body portion 88. Alternatively, both the upper box body portion 88 and the lower box body portion 84 may be moved up and down by connecting the moving units to both of them.

If the upper box body portion 88 is moved up and down, movement of the blocking member 72 and the connection pipe 78 is absorbed by providing extensible members such as the bellows 86 between the blocking member 72 and a connection site for the blocking member 72 or between the connection pipe 78 and a connection site for the connection pipe 78 so that the connection site (the discharging unit 50 or the vapor generating unit 20) for the blocking member 72 or the connection pipe 78 may not be damaged.

A case where the switch valves 70 have the individual box bodies 71 has been explained above, but the invention is not limited thereto.

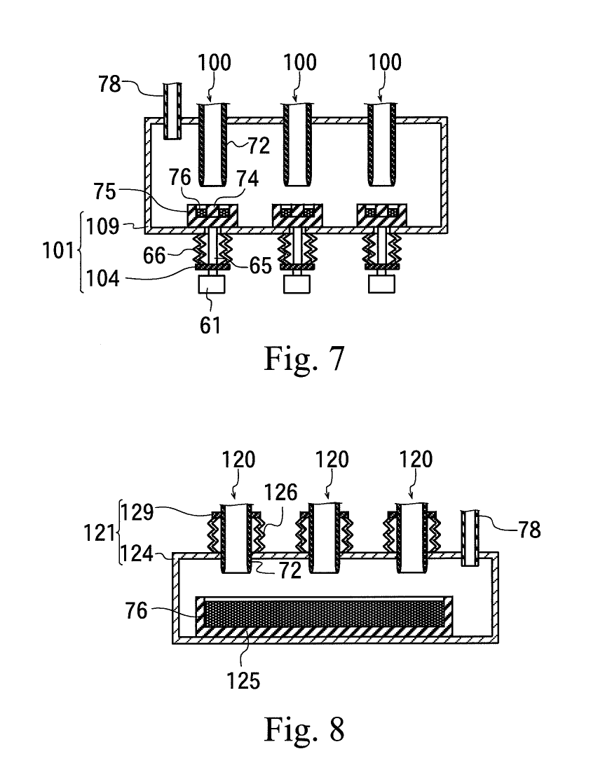

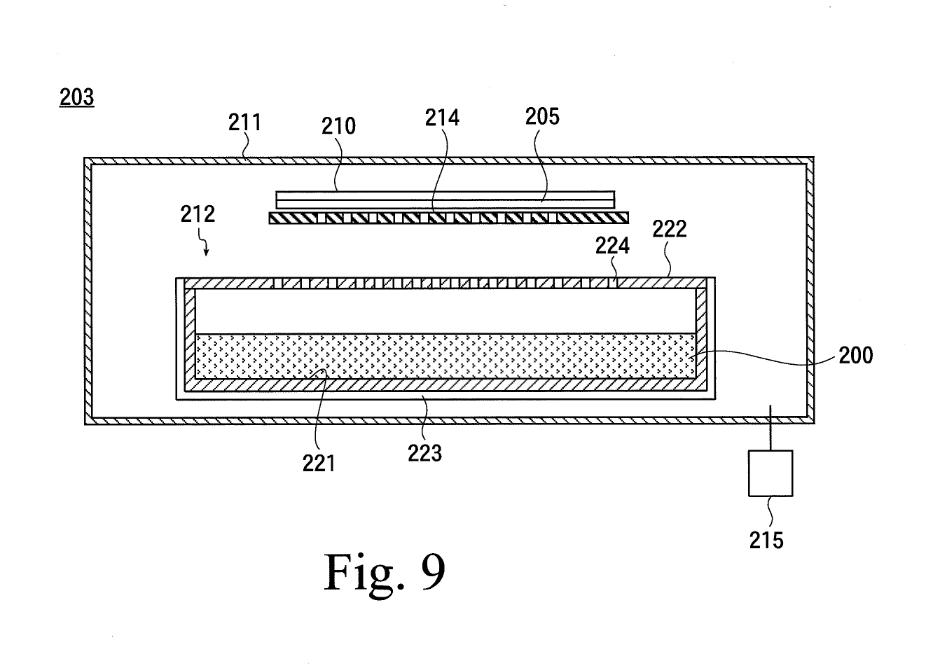

FIG. 7 illustrates switch valves 100 of a third embodiment of the present invention. Each switch valve 100 has a common box body 101, and a vessel 75 of each switch valve 100 is arranged inside the common box body 101. In the box body 101, an upper box body portion 109 is common, but lower box body portions 104 are formed for the respective switch valves 100.

As is the case with the switch valve 70 in FIG. 3, each of the lower box body portions 104 is connected to the upper box body portion 109 by extensible members such as bellows 66, and the lower box body portion 104, an upper shaft 65 and the vessel 75 together are moved up and down by the moving unit 61.

Blocking members 72 of the switch valves 100 are each gas-tightly inserted into the common upper box body portion 109. The positional relationship between the vessel 75 and the blocking member 72 is the same as in FIG. 3, and the low-melting point metal 76 placed in the vessel 75 and the blocking member 72 move relative to each other when each vessel 75 moves up and down.

Moving units 61 can individually move the vessels 75 up and down; and switching is performed between the opened state and the closed state by moving only the vessel 75 for a desired switch valve 100 up or down so that the vapor generating units 20 can be individually connected to or blocked from the discharging unit 50.

The above explanation is directed to the case where each of the switch valves 70, 80, 100 has the respective low-melting point metal 76, but the present invention is not limited thereto.

FIG. 8 illustrates switch valves 120 of a fourth embodiment of the present invention; each switch valve 120 has a common Low-melting point metal 76; and the low-melting point metal 76 is received directly in a lower box body portion 124 of a common box body 121, or received in a vessel 125 arranged in the lower box body portion 124.

In this embodiment, the lower box body portion 124 of each of the switch valves 120 is common; upper box body portions 129 are formed for the respective switch valves 120; each upper box body portion 129 is gas-tightly attached to the lower box body portion 124 by an extensible member such as a bellows 126; and an inner space of the box body 121 is blocked from the outside.

The lower box body portion 124 is fixed; the upper box body portion 129 is connected to a moving unit not shown; and each of the upper box body portions 129 can individually move up and down.

A blocking member 72 is inserted through each upper box body portion 129 in a manner such that an opening of a lower end is faced with the low-melting point metal 76. The blocking member 72 is fixed to the upper box body portion 129; and when the upper box body portion 129 moves up and down, the blocking member 72 moves up and down together with the upper box body portion 129 so that the blocking member 72 moves relative to the low-melting point metal 76.

The moving unit is able to individually move up and down the blocking member 72, and an opened state and a closed state are switched by moving up and down only the blocking member 72 for a desired switch valve 120, so that the vapor generating units 20 can be individually connected to or blocked from the discharging unit 50.

Since a site to which the blocking member 72 is connected may be damaged when the blocking member 72 moves, an extensible member (such as, a bellows or a plastic member) is desirably provided between the blocking member 72 and the connection site.

In the switch valves 100 of FIG. 7, the connection pipe 78 is connected to the upper box body portion 109; whereas, in the switch valves 120 of FIG. 8, a connection pipe is connected to the lower box portion 124. However, each switch valve 100, 120 and the connection pipe 78 are common, and an outer space of the blocking members 72 is common. Each of the vapor generating units 20 is connected to the blocking members 72, respectively; and the discharging unit 50 is connected to the connection pipe 78.

Although the low-melting point metal 76 is not particularly limited, when one having a melting point less than a decomposition temperature, at which the vapor of the vapor deposition material 39 is decomposed, is used and a film is formed by heating at a temperature less than the decomposition temperature, the vapor is not decomposed even upon contact with the low-melting point metal 76.

In the present invention, as described above, since the members contacting the vapor are heated to the heating temperature over the temperature at which the vapor of the vapor deposition material 39 forms a deposition, one having a melting point less than the mentioned heating temperature is used as the low-melting point metal 76.

For example, when the vapor deposition material 39 is an organic material for an organic EL element, the heating temperature is 250° C. or more and 400° C. or less, and at least one kind of metal selected from a group consisting of In (melting point 156° C.), Sn (melting point 232° C.) and an InSn alloy is used as the low-melting point metal 76.

If the vessel 75 and the projection 74 are made of a heat resistant material (such as, stainless steel), which does not melt at the above-described heating temperature, they are not deformed or melted even when the low-melting point metal 76 is melted.

The vapor deposition material 39 to be used in the vapor deposition apparatus 10b of the present invention is not particularly limited; and, for example, it is a powder having particle diameters of 100 μm or more and 200 μm or less.

A constituent material for the mounting member 24 is not particularly limited, and one, such as a metal, an alloy or an inorganic material, having a high heat conductivity is desired. Among them, silicon carbide (SiC) is particularly desired because it is excellent in both heat conductivity and mechanical strength.

The melted low-melting point metal 76 need not be ring shape, but when the low-melting point metals 76 are placed independently for the respective switch valves 70, if the low-melting point metal 76 is ring-shaped, it can obtain a higher heat efficiency and the amount of which the low-melting point metal 76 is used can be reduced.

The shape of the blocking member 72 is not particularly limited, but if a wall constituting the lower end is tapered and sharpened toward the tip, the low-melting point metal 76 is not spattered when the switch valve 70 is closed.

Further, if the relative movement amount between the low-melting point metal 76 and the blocking member 72 at a time when the switch valve 70 is closed is set in such a manner that the lower end of the blocking member 72 does not contact a bottom face of the vessel 75 (or the box body 85) and stops between the surface of the low-melting point metal 76 and the bottom face of the vessel 75 (or the box body 85), the lower end of the blocking member 72 is not in contact with a solid at any time. Thus, the switch valve 70 is not worn away even if it is repeatedly opened and closed.

The blocking member 72 is not limited to a tubular shape, and it can be designed in various shapes (such as a planar shape, or a spherical shape), if it can divide the inner space of the box body 71.

When the film is formed while the purge gas is introduced, an inert gas (Ar, Kr, Xe), which does not react with the vapor deposition material 39, is preferably used as the purge gas.

When the discharging unit 50 is heated, it is feared that the substrate 81 and the mask 16 are heated due to radiation heat. In particular, when the film is formed in a state such that the substrate 81 faces towards an area to which the discharge openings 55 are opposed, the substrate 81 is subject to be at a high temperature. Therefore, it is desirable that a cooling member 67 is arranged between the discharging unit 50 and the mask 16 or between the discharging unit 50 and the substrate 81 so that the substrate 81 may be kept at 60° C. or less by covering the discharging unit 50 with the cooling member 67.

Openings having a diameter larger than that of the discharge openings 55 are provided in those portions of the cooling member 67 which are opposed to the discharge openings 55 so that the vapor discharged through the discharge openings 55 may not form the deposition on the cooling member 67. The shapes of these openings or the positional relationship between the discharge openings and the openings of the cooling member 67 are not particularly limited, and one discharge opening may be exposed to one opening, or two or more discharge openings may be exposed to one opening.

In order to avoid deterioration of the vacuum deposition material 39 received in the tanks 31, each of the tanks 31 and the feeding units 30 is desirably kept at a temperature that is less than the evaporating temperature (less than 240° C., for example) of the vapor deposition material 39.

More specifically, a heat insulating member is provided in order to prevent heat from the heating chambers 29 or the like from being transmitted to the feeding units 30 and the tanks 31. Simultaneous with the effect of the heat insulating member, if either one or both of the feeding units 30 and the tanks 31 are cooled by cooling means, the deterioration of the vapor deposition material 39 can be more accurately prevented.

The vapor deposition material 39 is not limited to a mixture of a host, a dopant or the like. For example, constituents of the vapor deposition material 39 are received in tanks 31 of the different vapor generating units 20; the vapor generating units 20, in which the constituents are received, are respectively connected to the discharging unit 50; and a film may be formed by discharging a mixture of the vapors of the respective constituents through the discharge openings 55.

The color layers are not limited to a case where the light emitting layers containing the luminescent organic materials are formed, but the color layers may be formed, as a color filter, separately from the light-emitting layer.

The vapor deposition apparatus 10b of the present invention can be used for forming not only the light emitting layer but also other organic thin films (such as, a hole transport layer, a hole injection layer, an electron injection layer, or an electron transport layer).

It may be that the above-described vapor deposition apparatuses 10a to 10c are separately directed for RGB (red, green, blue), respectively; and hole transport layers, hole injection layers, light emitting layers, electron injection layers and electron transport layers for the respective colors may be formed by the respective vapor deposition apparatuses 10a to 10c.

It may be that either one or both of the discharging unit 50 and the mounting board 15 are connected to oscillating units 58 and the substrate 81 on the mounting board 15 and the discharging unit 50 are moved relative to each other during the film formation. More specifically, the substrate 81 is moved in such a way as to make reciprocating movement or circular movement within a plane. Since the positions, where the surface of the substrate 81 is opposed to the discharge openings 55, shift, the film thickness of the organic thin film grown on the surface of the substrate 81 becomes uniform.

The relative reciprocal movement direction between the mounting board 15 and the discharging unit 50 is not particularly limited. However either one or both of the discharging unit 50 and the mounting board 15 is reciprocally moved in a direction crossing the longitudinal direction of the discharge pipes 52 in order to make uniform the distribution in the film thickness.

The positional relationship between the substrate 81 and the discharging unit 50 is not particularly limited. In the case where the substrate 81 is small in size that sagging does not pose a problem, it may be that the discharge openings 55 are directed upwardly and the substrate 81 is arranged above the discharging unit 50, or it may be that the discharge openings 55 are directed laterally and the substrate 81 is erected on a side of the discharging unit 50.

A supplied amount of the vapor deposition material 39, which is required to form a film in a predetermined film thickness, is determined by a preliminary test. In the preliminary test, the same vapor deposition material 39 as that used in the actual film formation is received in the tank 31, a substrate 81 (the mask 16 and the substrate 81, if a mask 16 is used) is kept arranged above the discharging unit 50, and a thin film is formed by placing the vapor deposition material 39 on the mounting member 24 and generating the vapor under the same film forming condition including the pressure of the vacuum atmosphere, the temperature of the mounting member 24 or the like as that in the actual film formation. When the relationship between the falling amount of the vapor deposition material 39 and the film thickness of the thin film is determined, the necessary supplied amount is obtained based on this relationship.

The installation positions of the vapor generating units 20 and the switch valves 70 are not particularly limited; and either one or both of the vapor generating units 20 and the switch valves 70 may be arranged inside the film forming chamber 11, or may be arranged inside a vacuum chamber different from the film forming chamber 11.

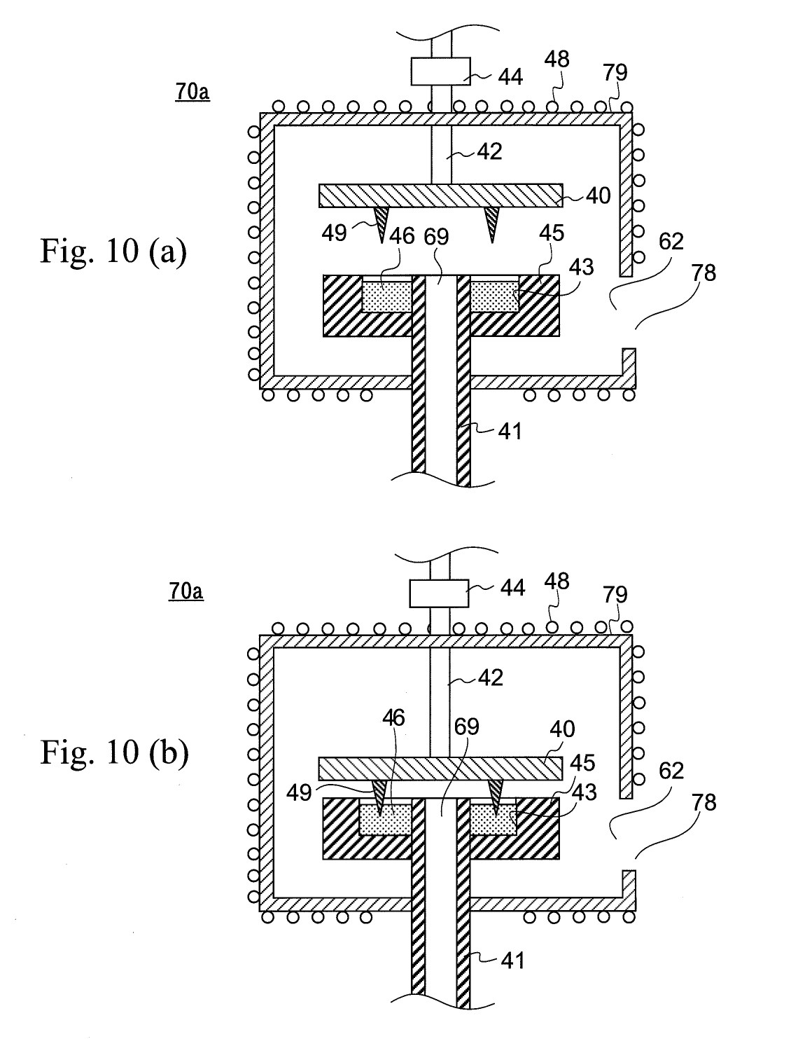

In the above explanation, the on-off opening 69 is provided at the lower end of the pipe, but as shown in FIGS. 10(a) and (b), it may be that the on-off opening is constituted by an opening at an upper end of a pipe 41 inserted through a bottom face of a vessel 43, and a blocking member 49 made of a tubular projection provided on a bottom face of a lid portion 40 is moved up and down in order to open or close the on-off opening 69 entirely and circumferentially surrounded by the vessel.

Explanation will be made of the switch valve 70a. In reference to FIGS. 10(a) and (b), in the switch valve 70a, a vessel body 45 is arranged inside a box body 79 being a housing. A pipe 41 is inserted into the vessel body 45, from a lower side of a bottom face of the vessel body 45, liquid-tightly between the bottom face of the vessel body 45 and the pipe 41, and the pipe 41 is projected above the bottom face of the vessel body 45.

The outer circumference of the pipe 41 is spaced apart from the inner circumferential face of the vessel body 45; and therefore, a portion of the pipe 41 above the bottom face of the vessel body 45 is surrounded by a ring-shaped vessel 43 constituted by the inner circumferential face and the bottom face of the vessel body 45 and the outer circumferential face of the pipe 41.

A low-melting point metal 46 is placed inside the ring-shaped vessel 43; and the low-melting point metal 46 is heated to a temperature of the melting point or more and melted by a heater 48 arranged outside the box body 79.

A lid portion 40 is arranged above the vessel 43.

A bottom face of the lid portion 40 faces towards the vessel 43; and the tubular blocking member 49 made of a ring-shaped projection is formed on the bottom face of the lid portion 40. The lid portion 40 and the blocking member 49 hinder the passage of a gas, and are mutually gas-tightly connected to each other.

A moving shaft 42 is connected to the lid portion 40, and the moving shaft 42 is gas-tightly extended to the outside of the box body 79, and connected to a motor 44. When the motor 44 is actuated, the lid portion 40 and the blocking member 49 are moved up and down through the moving shaft 42.

The box body 79 is provided with a connection opening 62 which is connected to either one of the vapor generating unit 20 and the discharging unit 50. The lower end portion of the pipe 41 is gas-tightly extended to the outside through the wall face of the box body 79; the upper end of that portion constituting the vessel 43 is designed as the on-off opening 69; and the lower end portion of the pipe 41 is connected to one of the vapor generating unit 20 and the discharging unit 50 which is not connected to the connection opening 62.

When the blocking member 49 and the lid portion 40 are spaced apart from the vessel 43 and the melted low-melting point metal 46, the connection pipe 78 and the on-off opening 69 are connected inside the box body 79, so that the vapor generating unit 20 and the discharging unit 50 are connected to each other.

When the lid portion 40 moves down and the blocking member 49 contacts and is immersed into the low-melting point metal 46 melted around the entire circumference of the on-off opening 69, the on-off opening 69 is covered with the lid portion 40 and the blocking member 49, and the connection pipe 78 is blocked from the on-off opening 69.

A similar effect is obtained in the case where the ring-shaped vessel 43 and the pipe 41 move, and the lid portion 40 does not move. The blocking member 49 does not contact the bottom face of the vessel body 45.

Furthermore, in the present invention, the low-melting point metal 46 is not particularly limited, and the low-melting point metal 46 having the melting point less than the decomposition temperature of the gas to be moved (for example, the vapor of the vapor deposition material) is used. When the low-melting point metal 46 is melted by heating at a temperature less than the decomposition temperature, the gas is not decomposed upon contact with the low-melting point metal 46.

Next, other embodiments of the present invention will be explained.

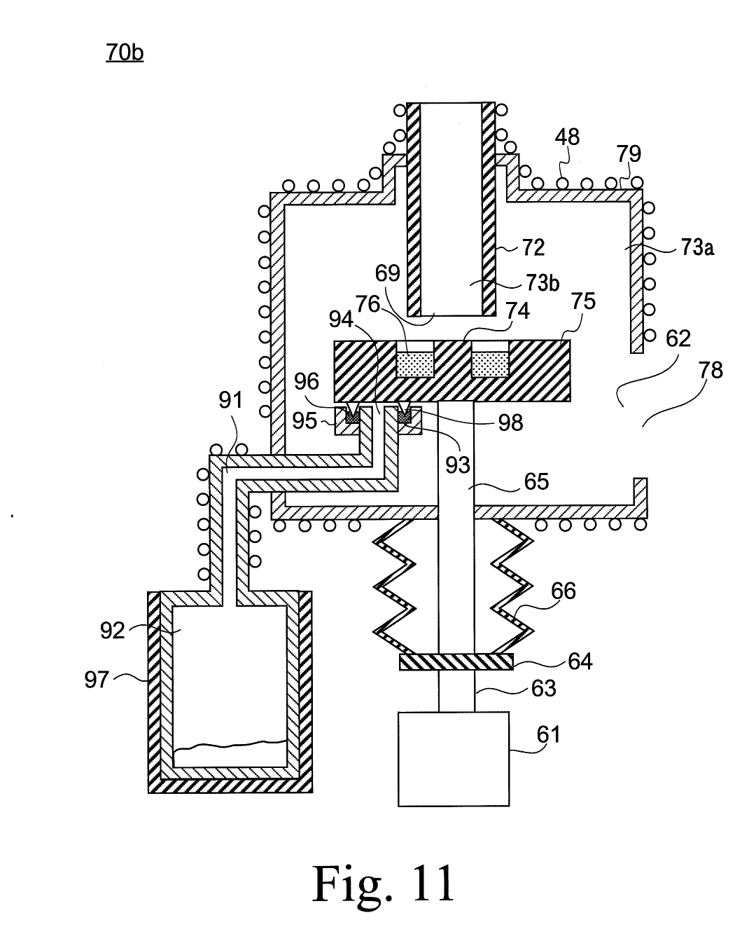

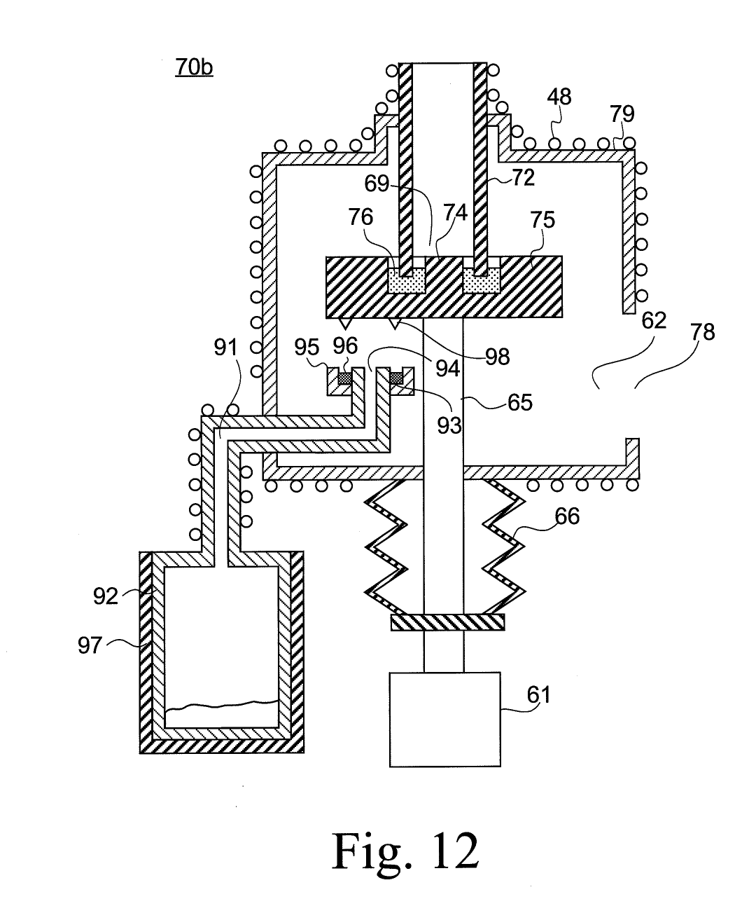

In FIGS. 11 and 12, a reference numeral 70b denotes another switch valve of the present invention.

A first vessel 75 is arranged inside a box body 79.

A pipe is gas-tightly inserted into the box body 79 above the first vessel 75. Assuming that a lower portion of the pipe is taken as a first blocking member 72, the first blocking member 72 is arranged above the first vessel 75.

The first vessel 75 is gas-tightly fitted to a moving means 61 (such as, a motor via an upper shaft 65), and is designed so as to be able to move up and down relative to the first blocking member 72.

A low-melting point metal 76 is placed inside the first vessel 75. The low-melting point metal 76 is melted; and a connection opening 62 provided in the box body 79 is communicated with a first on-off opening 69 surrounded by the blocking member 72, as shown in FIG. 11, in a non-contact state in which the first blocking member 72 is spaced apart from the melted low-melting point metal 76.

As shown in FIG. 12, when the first blocking member 72 contacts the melted low-melting point metal 76 inside the first vessel 75 and is immersed into the low-melting point metal 76, the connection opening 62 is blocked from the first on-off opening 69.

A vessel body 95 is arranged under the first vessel 75. As is the case with the switch valve 70a shown in FIGS. 10(a) and (b), a pipe 91 is connected to a bottom face of the vessel body 95, thereby forming a second vessel 93 in the form of a ring.

Assuming that an opening at an upper end of the pipe 91 inserted into the bottom face is taken as a second on-off opening 94, the second on-off opening 94 is surrounded by the second vessel 93.

A second tubular blocking member 98 made of a ring-shaped projection is adhered and gas-tightly formed onto a vertically downwardly directed rear face of the bottom face of the first vessel 75.

The second blocking member 98 is positioned above the second vessel 93; and the second blocking member 98 is designed so as to be inserted into and pulled out away from the second vessel 93 by an up and down movement of the first vessel 75.

A low-melting point metal 96 having the same composition as that of the low-melting point metal 76 inside the first vessel 75 is also placed inside the second vessel 93, and melted by rising temperature.

When the second blocking member 98 is inserted into the second vessel 93 and the second blocking member 98 contacts and is immersed into the low-melting point metal 96, the first vessel 75 becomes a lid portion for the second on-off opening 94, which is closed by the lid portion and the second blocking member 98. At this time, the first on-off opening 69 is opened, and the first on-off opening 69 is connected to the connection opening 62.

In a state where the first vessel 75 moves up and the first on-off opening 69 is closed, the second blocking member 98 is pulled away from the interior of the second vessel 93, the second blocking member 98 is spaced apart from the low-melting point metal 96, and the second blocking member 98 and the low-melting point metal 96 are in a non-contact state, whereby the second on-off opening 94 is opened. At this time, the first on-off opening 69 is closed, and the second on-off opening 94 is connected to the connection opening 62.

The pipe 91 having one end designed as the second on-off opening 94 is connected to a cooling tank 92 at the other end. The cooling tank 92 is provided at an outer circumference thereof with a cooling unit 97, and cooled. The connection opening 62 is connected to the vapor generating unit 20; and the first on-off opening 69 is connected to the discharging unit 50. When the first on-off opening 69 is closed and the second on-off opening 94 is opened, the vapor generating unit 20 is connected to the cooling tank 92, and the vapor of the organic compound produced in the vapor generating unit 20 is led into the cooling tank 92, and cooled by a cooling unit 97, so that the vapor forms a deposition on a wall face of the cooling tank 92. When the remaining vapor inside the vapor generating chamber 20 is to be removed, the remaining vapor can be removed through deposition by connecting the cooling tank 92 thereto.

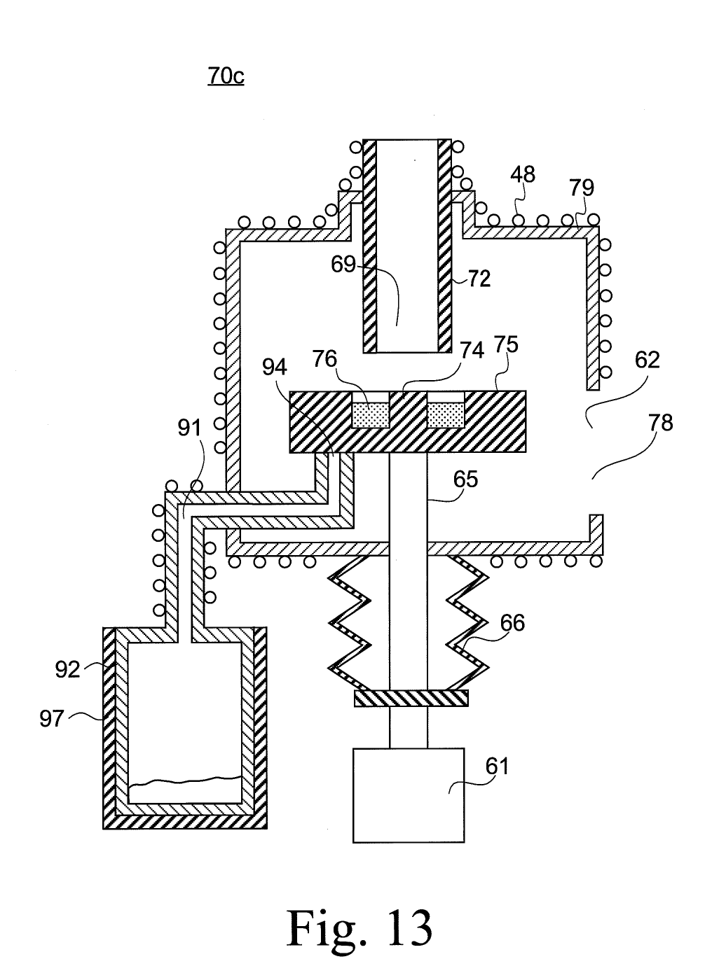

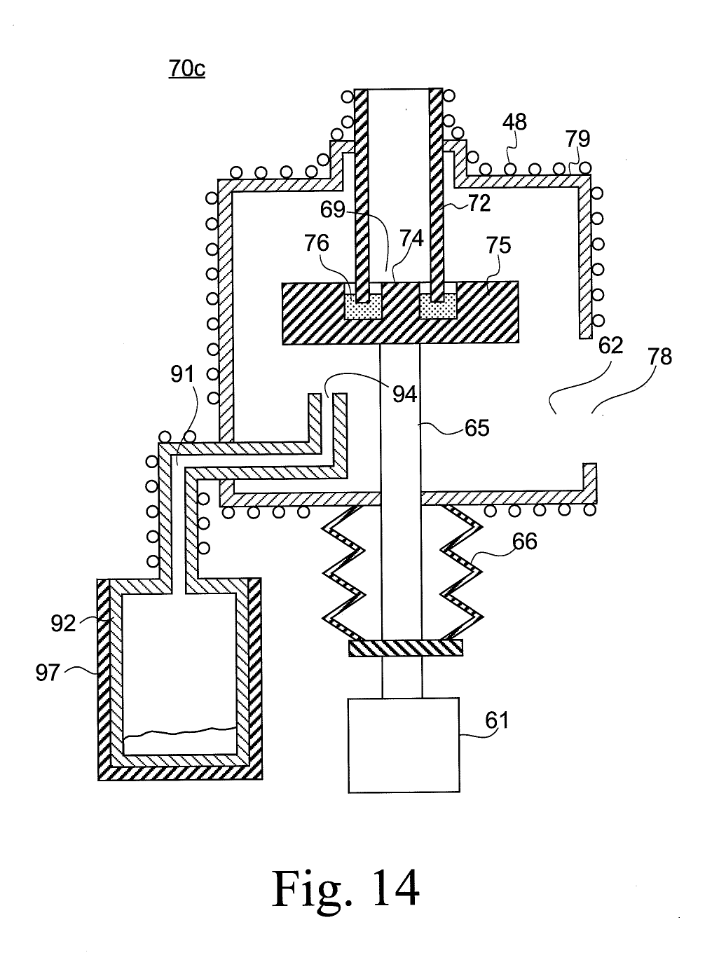

Furthermore, it may be that the vessel in which the low-melting point metal is placed is not provided at the tip of the pipe 91 connected to the cooling tank 92 in the box body 79, the second blocking member is not provided at the bottom face of the first vessel 75, and the second on-off opening 94 at the tip of the pipe 91 is opened and closed by attaching and detaching the box body relative to the tip of the pipe 91. The second on-off opening 94 in FIG. 13 is in the closed state, while in FIG. 14 it is in the opened state.

What is claimed is:

1. A film forming source, comprising:
a vapor generating unit for generating a vapor of a vapor deposition material therein; a discharging unit for discharging the vapor of the vapor deposition material; and a switch valve for switching connection and blocking between the vapor generating unit and the discharging unit,
wherein the switch valve includes a box body, a vessel which is arranged inside the box body and in which a melted metal is to be placed, the melted metal being placed in the vessel, a blocking member having a lower end being capable of contacting the melted metal, and a moving unit which closes the switch valve by relatively moving the blocking member and contacting the lower end of the blocking member with a surface of the melted metal and opens the switch valve by spacing the lower end of the blocking member apart from the surface of the melted metal.

2. The film forming source according to claim 1, further comprising a plurality of the vapor generating units, wherein connection and blocking between the vapor generating units and the discharging unit can be individually switched by the switch valve.

3. The film forming source according to either claim 1 or claim 2, wherein the blocking member is in the form of a tube, wherein the lower end of the blocking member is configured by a lower end of the tube, wherein either one of the discharging unit and the vapor generating units is connected to an inner space of the tube, while the other is connected to an outer space of the tube.

4. The film forming source according to claim 1, further comprising a pipe having a tip inserted into the box body and surrounded by the vessel; and a lid portion, wherein the tubular blocking member which comprises a ring-shaped projection formed projectingly from a bottom face of the lid portion is formed on the bottom face of the lid portion, wherein when the blocking member contacts the low-melting point metal melted inside the vessel over an outer circumference of the pipe, an on-off opening is blocked by the blocking member and the lid portion and the switch valve is closed, and wherein when the blocking member moves away from the low-melting point metal, the switch valve is opened.

5. The film forming source according to claim 1, wherein the discharging unit includes a plurality of elongate discharge pipes arranged parallel to each other, a discharge opening is provided in each of the discharge pipes, respectively, and when the vapor generating units are connected to the discharging unit, the vapor of the vapor deposition material is fed into each of the discharge pipes, respectively, and the vapor of the vapor deposition material is discharged through each of the discharge openings.

6. A vapor deposition apparatus, comprising:
a film forming chamber; and
a film forming source of claim 1,
wherein the discharging unit discharges the vapor of the vapor deposition material into the film forming chamber.

7. The vapor deposition apparatus according to claim 6, further comprising a mounting board which is arranged inside the film forming chamber and on a surface of which a substrate is to be placed, wherein the discharging unit discharges the vapor of the vapor deposition material toward the mounting board from a position above the mounting board.

8. The vapor deposition apparatus according to claim 7, further comprising an oscillating unit connected to at least one of the mounting board and the discharging unit, wherein the oscillating unit moves the discharging unit relative to the substrate within a plane parallel to the substrate placed on the mounting board.

9. A manufacturing apparatus for an organic EL element, comprising:
a transfer chamber;
a sputtering chamber; and
a vapor deposition apparatus of claim 6,
wherein the sputtering chamber and the vapor deposition apparatus are connected to the transfer chamber.
